(19) United States
(12) Patent Application Publication
(10) Pub. No.: US 2009/0166789 A1
(43) Pub. Date: Jul. 2, 2009

(54) IMAGE SENSOR AND METHOD FOR MANUFACTURING THE SAME

(76) Inventor: Hee-Sung Shim, Gangneung-si (KR)

Correspondence Address: SHERR & VAUGHN, PLLC, 620 HERNDON PARKWAY, SUITE 200, HERNDON, VA, 20170, US

(21) Appl. No.: 12/344,539

(22) Filed: Dec. 28, 2008

(30) Foreign Application Priority Data
Dec. 28, 2007 (KR) 10-2007-0139748

(51) Int. Cl. H01L 31/103; H01L 31/18

(52) U.S. Cl. 257/459; 438/98; 257/E31.057; 257/E31.11

(57) ABSTRACT

An image sensor includes a first substrate and a photodiode. A circuitry including a metal interconnection is formed over the first substrate. The photodiode is formed over a first substrate, and contacts the metal interconnection. The circuitry of the first substrate includes a transistor over the first substrate, an electrical junction region at a side of the transistor, and a first conduction type region. The first conduction type region is connected to the metal interconnection and contacts the electrical junction region.

The present application claims priority under 35 U.S.C. 119 to Korean Patent Application No. 10-2007-0139748 (filed on Dec. 28, 2007) which is hereby incorporated by reference in its entirety.

### BACKGROUND

An image sensor is a semiconductor device for converting an optical image into an electrical signal. In general, image sensors may be classified as either a charge coupled device (CCD) image sensor or a complementary metal oxide silicon (CMOS) image sensor (CIS). During the fabrication of image sensors, a photodiode may be formed in a substrate using ion implantation. As the size of a photodiode is reduced for the purpose of increasing the number of pixels without increasing chip size, the area of a light receiving portion is also reduced, thereby resulting in a reduction in image quality. Also, because a stack height does not reduce as much as the reduction in the area of the light receiving portion, the number of photons incident to the light receiving portion is also reduced due to a diffraction of light effect called “Airy disk”.

Techniques for forming a related photodiode include using amorphous silicon (Si), or forming a readout circuitry in a silicon (Si) substrate using a method such as wafer-to-wafer bonding, and forming a photodiode on and/or over the readout circuitry (referred to as a “three-dimensional (3D) image sensor). The photodiode is connected to the readout circuitry through a metal interconnection. Because both the source and the drain on both sides of the transfer transistor are heavily doped with n-type impurities, a charge sharing phenomenon may occur. When the charge sharing phenomenon occurs, the sensitivity of an output image is reduced and an image error may be generated. Also, because a photo charge may not readily move between the photodiode and the readout circuitry, a dark current may be generated and/or saturation and sensitivity may be reduced.

### SUMMARY

Embodiments relate to an image sensor and a manufacturing method thereof that prevent occurrence of charge sharing while maximizing a fill factor. Embodiments relate to an image sensor and a manufacturing method thereof that minimizes a dark current source and minimizes reduction in saturation and sensitivity by providing a swift movement path for a photo charge between a photodiode and a readout circuitry.

Embodiments relate to an image sensor including: a first substrate over which circuitry including a metal interconnection is formed; and a photodiode over the first substrate, the photodiode contacting the metal interconnection, wherein the circuitry of the first substrate includes: a transistor over the first substrate; an electrical junction region at a side of the transistor; and a first conduction type region connected to the metal interconnection and contacting the electrical junction region.

Embodiments relate to an image sensor including: a first substrate over which circuitry including a metal interconnection is formed; and a photodiode over the first substrate, the photodiode contacting the metal interconnection, wherein the circuitry includes: a transistor over the first substrate; an electrical junction region at a side of the transistor; and a first conduction type region connected to the metal interconnection and contacting the electrical junction region. The electrical junction region may have an upper portion doped with second conduction type impurities.

Embodiments relate to a method for manufacturing an image sensor including: forming circuitry including a metal interconnection over a first substrate; and forming a photodiode over the metal interconnection, wherein the forming of the circuitry of the first substrate includes: forming a transistor over the first substrate; forming an electrical junction region at a side of the transistor; and forming a first conduction type region that is connected to the metal interconnection and in contact with the electrical junction region.

### DRAWINGS

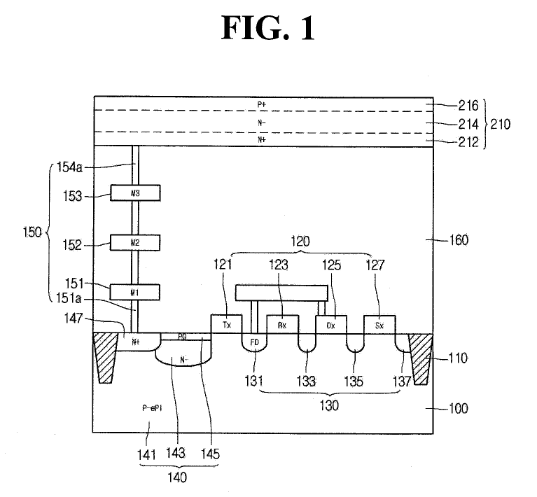

Example FIGS. 1 through 7 illustrate an image sensor and a method for manufacturing an image sensor in accordance with embodiments.

### DESCRIPTION

In the description of embodiments herein, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

Example FIG. 1 is a sectional view of an image sensor in accordance with embodiments. As illustrated in example FIG. 1, an image sensor in accordance with embodiments may include: first substrate 100 on which metal interconnection 150 and circuitry are formed; and photodiode 210 contacting metal interconnection 150 and formed on first substrate 100. The circuitry of first substrate 100 may include: transistor 120 over first substrate 100; electrical junction region 140 at a side of transistor 120; and high concentration first conduction type region 147 connected to metal interconnection 150 and in contact with electrical junction region 140.

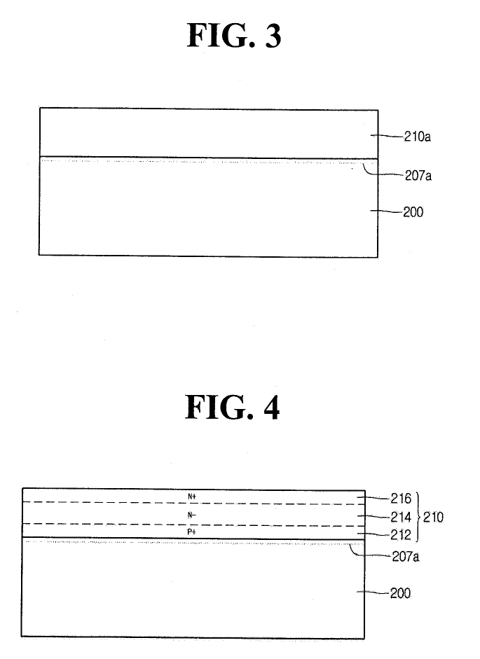

In the image sensor illustrated in example FIG. 1, photodiode 210 may be formed in crystalline semiconductor layer 210a (see example FIG. 3). In accordance with embodiments, because the image sensor may employ a photodiode that is positioned over a circuitry, and the photodiode is formed in the crystalline semiconductor layer, generation of a defect inside the photodiode can be minimized, or even prevented. The circuitry may include transistor 120 and metal interconnection 150.

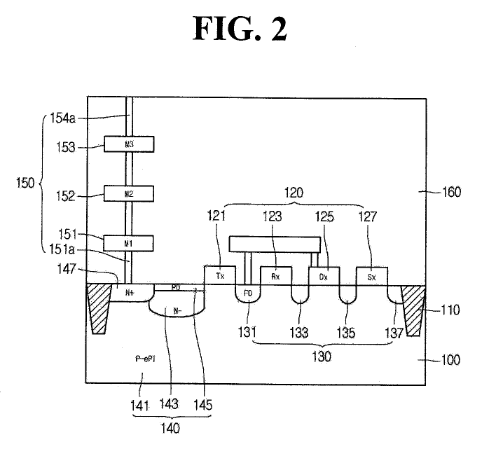

Hereinafter, a method for manufacturing an image sensor in accordance with embodiments will be described with reference to example FIGS. 2 to 6. As illustrated in example FIG. 2, a method for manufacturing an image sensor in accordance with embodiments includes preparing first substrate 100 over which metal interconnection 150 and circuitry are formed. First substrate 100 may be, but is not limited to, a second conduction type substrate. For example, device isolation layer 110 is formed in second conduction type first substrate 100 to thereby define an active region. The circuitry including transistor 120 may be formed in the active region. For example, transistor 120 may include transfer transistor (Tx) 121, reset transistor (Rx) 123, drive transistor (Dx) 125, and select transistor (Sx) 127. Ion implantation region 130 including floating diffusion region (FD) 131 and source/drain regions 133, 135, and 137 may then be formed.

A process of forming the circuitry on first substrate 100 in embodiments will be more fully described below. Transistor 120 may be formed on first substrate 100 and may be, but is not limited to, a transfer transistor (Tx). Electrical junction region 140 may be formed at one side of transistor 120. For example, electrical junction region 140 may be, but is not limited to, a PN junction. For example, electrical junction region 140 may include first conduction type ion implantation layer 143 formed on second conduction type well 141 or a second conduction type epitaxial layer, and second conduction type ion implantation layer 145 formed on first conduction type ion implantation layer 143. For instance, as illustrated in example FIG. 2, PN junction 140 may be, but is not limited to, a P0 (145)/N− (143)/P− (141) junction.

High concentration first conduction type region 147 may be connected to metal interconnection 150 and may contact electrical junction region 140. High concentration first conduction type region 147 may be, but is not limited to, a high concentration N+ ion impanation region, i.e., N+ junction. For example, high concentration first conduction type region 147 may be formed to contact a side of electrical junction region 140, but is not limited thereto. That is, high concentration first conduction type region 147 may be electrically connected to first conduction type ion implantation layer 143 of electrical junction region 140.

Contact plug 151a of metal interconnection may be formed over high concentration first conduction type region 147. The readout circuit of embodiments allows electrons generated from the photodiode disposed in an upper portion of a chip to move toward N+ junction 147 of the substrate 100 through metal interconnection 150, and also allows electrons in N+ junction 147 to move toward N− junction 143. This allows 4T operation.

Meanwhile, to connect photodiode 210 disposed over the chip to first substrate 100, n-type impurities are heavily doped to form high concentration first conduction type region 147 for achieving ohmic contact. If a source and a drain of transfer transistor (Tx) 121 were connected to high concentration first conduction type region 147, the source and the drain may have the same potential, leading to saturation reduction and sensitivity reduction due to a charge sharing while a signal is being read out. In embodiments, therefore, electrical junction region 140, e.g., P0/N−/P− junction may be formed in first substrate 100 as illustrated in example FIG. 2.

Unlike a node of floating diffusion (FD) 131, which is an N+ junction, P0/N−/P− junction 140 (electrical junction region 140 to which an applied voltage may not be not fully transferred) is pinched-off at a predetermined voltage. This voltage is called a pinning voltage and may depend on the doping concentrations of P0 region 145 and N− region 143. An electron generated from photodiode 210 in an upper portion of a chip moves to P0/N−/P− junction 140, and is delivered to the node of floating diffusion (FD) 131 and converted into a voltage when transfer transistor (Tx) 121 is turned on.

Because a maximum voltage value of P0/N−/P− junction 140 becomes a pinning voltage, and a maximum voltage value of the node of floating diffusion (FD) 131 becomes a voltage value obtained by subtracting a threshold voltage (Vth) of reset transistor (Rx) 123 from Vdd voltage, an electron generated from photodiode 210 in the upper portion of a chip can be fully dumped to the node of floating diffusion (FD) 131 without charge sharing by a potential difference between both sides of transfer transistor (Tx) 121. Therefore, unlike a case where a photodiode is simply connected to an N+ junction, limitations such as saturation reduction and sensitivity reduction can be minimized, or even avoided, in accordance with embodiments.

In accordance with embodiments, N+ junction 147 for ohmic contact may be formed on, or over, the surface of P0/N−/P− junction 140. A process of forming N+ junction 147 and M1C contact 151a may provide a leakage source. This is because the device operates with a reverse bias applied to P0/N−/P− junction 140 and thus an electric field may be generated on the Si surface. A crystal defect generated during the contact forming process inside the electric field may serve as a leakage source. Also, in a case where N+ junction 147 is formed on the surface of P0/N−/P− junction 140, an electric field can be further generated due to N+/P0 junction 147/141, which also provides a leakage source.

Therefore, in a layout in accordance with embodiments, contact 151a may be formed in an active region not doped with a P0 layer but including N+ junction 147 and may be connected to N− junction 143. Consequently, the electric field may not be generated on the Si surface, which can contribute to reduction in a dark current of a 3D integrated CIS.

Interlayer dielectric 160 may be formed on, or over, first substrate 100, and metal interconnection 150 can also be formed. Metal interconnection 150 may include, but is not limited to, first metal contact 151a, first metal 151, second metal 152, third metal 153 and fourth metal contact 154a.

As illustrated in example FIG. 3, crystalline semiconductor layer 210a may be formed on second substrate 200. Since photodiode 210 may formed in crystalline semiconductor layer 210a, a defect inside the photodiode can be minimized, or even prevented. For example, crystalline semiconductor layer 210a may be formed on, or over, second substrate 200 by an epitaxial growth method. After that, hydrogen ions may be implanted into an interface between second substrate 200 and crystalline semiconductor layer 210a to form hydrogen ion implantation layer 207a. The implanting of hydrogen ions may be performed after implanting impurity ions for the formation of photodiode 210.

As illustrated in example FIG. 4, impurity ions may be implanted into crystalline semiconductor 210a to form photodiode 210. For example, second conduction type conduction layer 216 may be formed in an upper portion of crystalline semiconductor layer 210a. Second conduction type conduction layer 216 may be a high concentration p-type conduction layer. For example, high concentration p-type conduction layer 216 may be formed on, or over, crystalline semiconductor layer 210a by performing a first blanket-ion implantation onto substantially the entire surface of second substrate 200 without a mask. For example, second conduction type conduction layer 216 may be formed at a junction depth of less than about 0.5 μm.

After that, first conduction type conduction layer 214 may be formed under second conduction type conduction layer 216 by performing a second blanket-ion implantation onto substantially the entire surface of second substrate 200 without a mask. First conduction type conduction layer 214 may be a low concentration n-type conduction layer. Low concentration first conduction type conduction layer 214 may be formed at a junction depth ranging from about 1.0 μm to about 2.0 μm.

Afterwards, in accordance with embodiments, high concentration first conduction type conduction layer 212 may be formed under first conduction type conduction layer 214. For example, high concentration N+ conduction layer 212 may be formed under first conduction type conduction layer 214 by performing a third blanket-ion implantation onto substantially the entire surface of second substrate 200 without a mask, so that high concentration N+ conduction layer 212 can contribute to ohmic contact.

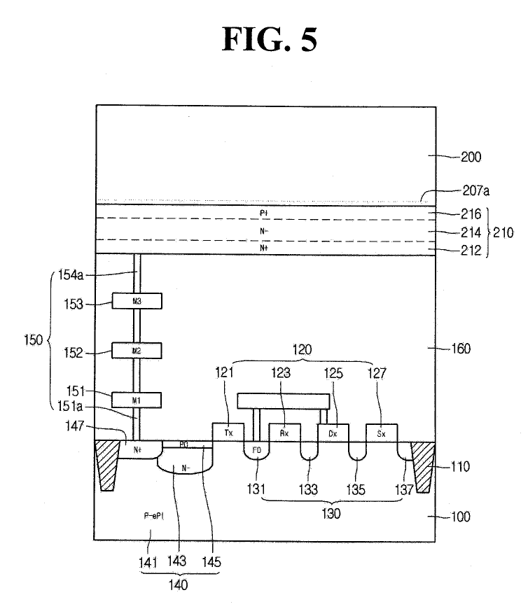

As illustrated in example FIG. 5, first substrate 100 and second substrate 200 may be bonded to each other such that photodiode 210 contacts metal interconnection 150. For example, the bonding may be performed by contacting first substrate 100 and second substrate 200 with each other and then performing activation by plasma to increase a surface energy in a bonding surface. Thereafter, hydrogen ion implantation layer 207a can be changed into hydrogen gas layer by performing heat treatment on second substrate 200.

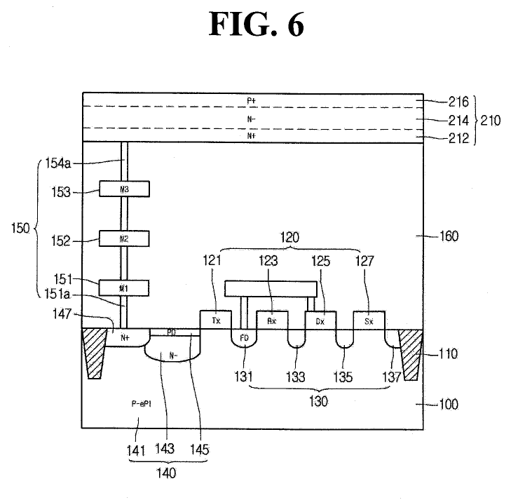

As illustrated in example FIG. 6, a portion of second substrate 200 can then be removed with photodiode 210 left under the hydrogen gas layer so that photodiode 210 can be exposed. The removal of second substrate 200 can be performed, for example, by using a cutting apparatus such as a blade. Next, an etching process for separating photodiode 210 for each unit pixel may be performed. The etched portion can then be filled with an interpixel dielectric. After that, processes for forming an upper electrode and a color filter may be performed.

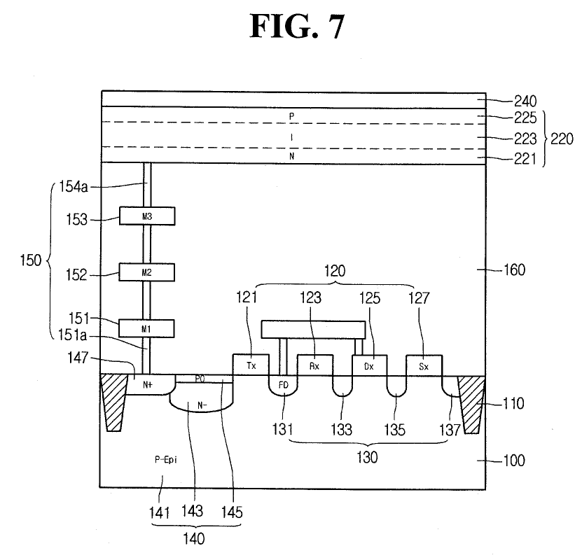

Example FIG. 7 is a sectional view of an image sensor in accordance with embodiments in which photodiode 220 may be formed in an amorphous layer. For example, photodiode 220 may include: intrinsic layer 223 electrically connected to metal interconnection 150; and second conduction type conduction layer 225 on, or over, intrinsic layer 223. The image sensor may further include first conduction type conduction layer 221 between metal interconnection 150 and intrinsic layer 223. A process of forming photodiode 220 in accordance with embodiments will now be described below. Photodiode 220 may be formed, not by bonding, but by performing a deposition process on, or over, first substrate 100 on which circuitry 120 including metal interconnection 150 is formed.

For example, first conduction type conduction layer 221 may be formed on, or over, first substrate 100 such that first conduction type conduction layer 221 contacts metal interconnection 150. If desired, a subsequent process may be performed without forming first conduction type conduction layer 221. First conduction type conduction layer 221 may act as an N-layer of a PIN diode employed in embodiments. That is, first conduction type conduction layer 221 may be, but is not limited to, an N-type conduction layer.

First conduction type conduction layer 221 may be formed of n-doped amorphous silicon, but is not limited thereto. That is, first conduction type conduction layer 221 may be formed of a-Si:H, a-SiGe:H, a-SiC, a-SiN:H, a-SiO:H or the like which is formed by adding Ge, C, N, O or the like to amorphous silicon. Also, first conduction type conduction layer 221 may be formed for example by chemical vapor deposition such, as, for example, plasma enhanced CVD. For example, first conduction type conduction layer 221 may be formed of amorphous silicon by a PECVD in which PH₃, P₂H₅ and the like are mixed with Silane (SiH₄) gas.

Intrinsic layer 223 may be formed on, or over, first conduction type conduction layer 221 and may act as an I-layer of the PIN diode employed in embodiments. Intrinsic layer 223 may be formed of amorphous silicon and may be formed by a CVD such as, for example, a PECVD. For example, intrinsic layer 223 may be formed of amorphous silicon by a PECVD using silane (SiH₄) gas.

After that, second conduction type conduction layer 225 may be formed on, or over, intrinsic layer 223. Second conduction type conduction layer 225 and intrinsic layer 223 may be formed in-situ. Second conduction type conduction layer 225 may act as a P-layer of the PIN diode employed in embodiments. That is, second conduction type conduction layer 225 may be but is not limited to a p-type conduction layer. Second conduction type conduction layer 225 may be formed of P-doped amorphous silicon, but is not limited thereto.

Second conduction type conduction layer 225 may also be formed by a CVD such as, for example, a PECVD. For example, second conduction type conduction layer 225 may be formed of amorphous silicon by a PECVD in which boron (B) or the like is mixed with silane (SiH₄) gas. Next, upper electrode 240 may be formed on second conduction type conduction layer 225. Upper electrode 240 may be formed of a transparent electrode material having a high light transmission and a high conductivity. For example, upper electrode 240 may be formed of indium tin oxide (ITO), cadmium tin oxide (CTO) or the like.

The image sensor and manufacturing method thereof in accordance with embodiments can provide a vertical integration of the circuitry and the photodiode. In accordance with embodiments, a method for manufacturing a 3-dimensional (3D) image sensor having a vertical configuration can provide correlated double sampling (CDS) as same as the case of 4-Tr pixel operation while minimizing a dark current that may be generated during a contact-etching process of connecting a photodiode formed in an upper portion of a chip to a substrate (Si-sub) with a circuitry formed, and a high concentration N+ doping process. Consequently, noise as well as the dark current may be minimized.

Furthermore, in accordance with embodiments, the vertical integration of the circuitry and the photodiode may obtain a fill factor close to 100%. In addition, in accordance with embodiments, the vertical integration of the circuitry and the photodiode may provide a sensitivity higher than that in related sensors by virtue of a vertical integration despite the same pixel size. Although embodiments relate generally to a complementary metal oxide semiconductor (CMOS) image sensor, such embodiments are not limited CMOS sensors but may be readily applied to any image sensor utilizing a photodiode.

It will be obvious and apparent to those skilled in the art that various modifications and variations can be made in the embodiments disclosed. Thus, it is intended that the disclosed embodiments cover the obvious and apparent the modifications and variations, provided that they are within the scope of the appended claims and their equivalents.

What is claimed is:

1. An image sensor comprising:
a first substrate over which circuitry including a metal interconnection is formed; and
a photodiode over the first substrate, the photodiode contacting the metal interconnection,
wherein the circuitry of the first substrate comprises:
a transistor over the first substrate;
an electrical junction region at a side of the transistor; and
a first conduction type region connected to the metal interconnection and contacting the electrical junction region.

2. The image sensor of claim 1, wherein the first conduction type region contacts a side of the electrical junction region.

3. The image sensor of claim 2, wherein a contact plug of the metal interconnection is disposed over the first conduction type region.

4. The image sensor of claim 1, wherein the electrical junction region comprises a PN junction.

5. The image sensor of claim 1, wherein the electrical junction region comprises a PNP junction.

6. The image sensor of claim 1, wherein the electrical junction region has an upper portion doped with p-type impurities, and the electrical junction region comprises a PN junction.

7. The image sensor of claim 1, wherein the transistor comprises a transfer transistor.

8. An image sensor comprising:
a first substrate over which circuitry including a metal interconnection is formed; and
a photodiode over the first substrate, the photodiode contacting the metal interconnection,
wherein the circuitry comprises:
a transistor over the first substrate;
an electrical junction region at a side of the transistor; and
a first conduction type region connected to the metal interconnection and contacting the electrical junction region,
wherein the electrical junction region has an upper portion doped with second conduction type impurities.

9. The image sensor of claim 8, wherein the first conduction type region contacts a side of the electrical junction region.

10. The image sensor of claim 9, wherein a contact plug of the metal interconnection is disposed over the first conduction type region.

11. The image sensor of claim 8, wherein the electrical junction region has an upper portion doped with p-type impurities, and the electrical junction region comprises a PN junction.

12. The image sensor of claim 8, wherein the transistor comprises a transfer transistor.

13. The image sensor of claim 8, wherein the electrical junction region comprises a PNP junction.

14. A method for manufacturing an image sensor, the method comprising:
forming circuitry including a metal interconnection over a first substrate; and
forming a photodiode over the metal interconnection,
wherein the forming of the circuitry of the first substrate comprises:
forming a transistor over the first substrate;
forming an electrical junction region at a side of the transistor; and
forming a first conduction type region that is connected to the metal interconnection and contacts the electrical junction region.

15. The method of claim 14, wherein forming of the first conduction type region comprises:
forming the first conduction type region so as to contact a side of the electrical junction region.

16. The method of claim 15, wherein forming of the first conduction type region comprises:
forming a contact plug of the metal interconnection over the first conduction type region.

17. The method of claim 14, wherein the forming of the electrical junction region comprises forming a PN junction.

18. The method of claim 14, wherein the forming of the electrical junction region comprises forming a PNP junction.

19. The method of claim 14, wherein forming the electrical junction region includes doping an upper portion with second conduction type impurities.

20. The method of claim 19, wherein the electrical junction region comprises a PN junction.
